(19) United States
(12) Patent Application Publication
(10) Pub. No.: US 2014/0354296 A1
(43) Pub. Date: Dec. 4, 2014

(54) SIGNAL TEST DEVICE

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventor: XIAO-QING YAN, Shenzhen (CN)

(73) Assignees: HONG FU JIN PRECISION INDUSTRY (ShenZhen) CO., LTD, Shenzhen (CN); HON HAI PRECISION INDUSTRY CO., LTD., New Taipei (TW)

(21) Appl. No.: 14/288,620

(22) Filed: May 28, 2014

(30) Foreign Application Priority Data
May 30, 2013 (CN) 2013102113048

(51) Int. Cl. G01R 31/04

(52) U.S. Cl. CPC G01R 31/045
USPC 324/538

(57) ABSTRACT

A signal test device for testing a tested interface includes a circuit board. The circuit board includes a processer, a first relay unit, a second relay unit, a selection relay unit, a channel selection key, a speed selection key, a channel display unit, a speed display unit, and an edge connector electrically connected to tested pins of the tested device. Each of the first and second relay units includes a plurality of relays. When a user presses the channel selection key and the speed selection key, a code and a speed of a tested signal output from tested interface can be tested conveniently and accurately, with a high-speed transmission through the first and second relay units, and can be shown on the the channel display unit and the speed display unit.

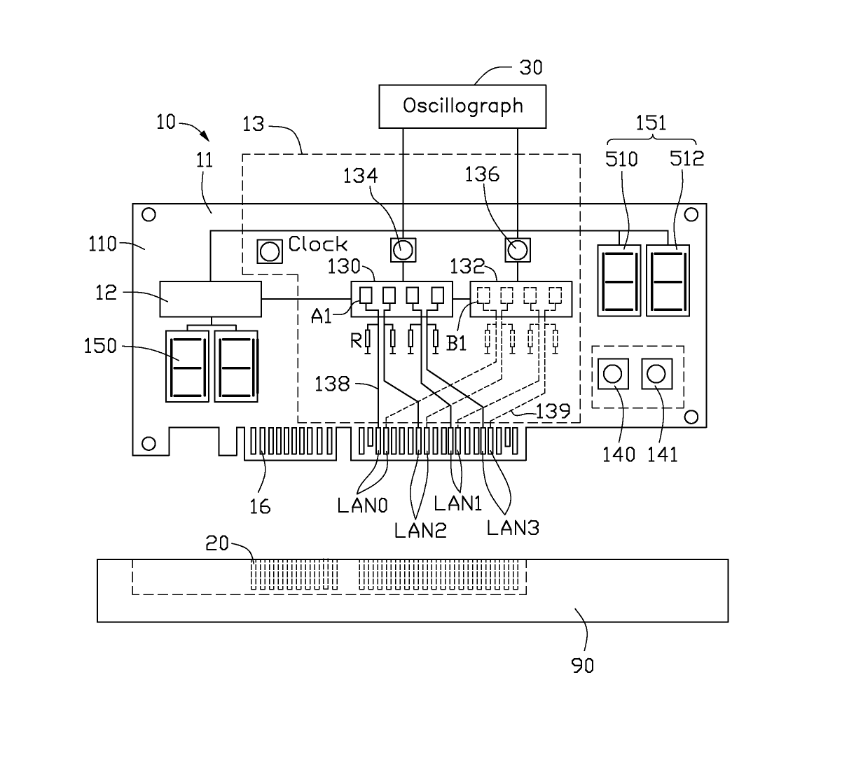

### FIELD

The present disclosure relates to a signal test device.

### BACKGROUND

Signals of peripheral component interconnect express (PCIE) interfaces can be tested using a test device, such as an oscillograph, through a plurality of cables. However, after a test of one group of signals is completed, the cables need to be disconnected from the PCIE interface, and be connected to the next group of signals to be tested, which is inconvenient and non-efficient.

Therefore, there is need for improvement in the art.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the present disclosure.

The figure is a schematic diagram of an embodiment of a signal test device electrically connected to a tested interface and an oscillograph.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The phrase “a plurality of” means “at least two.”

The figure shows an embodiment of a signal test device 10 including a circuit board 11 electrically connected between a tested interface 20 on a motherboard and an oscillograph 30, for testing the tested interface 20. In the embodiment, the tested interface 20 is a peripheral component interconnect express (PCIE) slot.

The circuit board 11 includes a processor 12 and a plurality of electrical components.

The electrical components may include a signal transmission unit 13, a channel selection key 140, a speed selection key 141, a channel display unit 150, a speed display unit 151, and an edge connector 16. The edge connector 16 is set on an edge of the circuit board 11 and accords to a standard of the PCIE connector, for electrically connecting to the tested interface 20 to transmit data. In the embodiment, the processor can be a single-chip or a programmable logic controller.

The channel selection key 140 is used for sending a first selection signal to the processor 12 to select one group of tested pins of the tested interface 20. The channel display unit 150 is used for displaying a corresponding code of one group of tested pins currently selected by the channel selection key 140. The speed selection key 141 is used for sending a second selection signal to the processor 12 to select a speed type of the group of tested pins currently selected by the channel selection key 140. The speed display unit 151 is used for displaying a speed code of the group of tested pins currently selected by the speed selection key 141.

The signal transmission unit 13 includes a first relay unit 130, a second relay unit 132, a first signal terminal 134 electrically connected to the first relay unit 130 and a second signal terminal 136 electrically connected to the second relay unit 132. The first and second signal terminals 134, 136 are electronic connected to two signal detection terminals 31 of the oscillograph 30, respectively. In the embodiment, the first relay unit 130 includes four relays A1. The second relay unit 132 includes four relays B1. The first relay unit 130 is arranged on a front surface 110 of the circuit board 11. The second relay unit 132 is arranged on a rear surface opposite to the front surface 110 of the circuit board 11.

In the embodiment, the edge connector 16 includes first to fourth pairs of signal pins LAN0, LAN1, LAN2, LAN3. Each pair of signal pins LAN0-LAN3 is used for transmitting a differential pair of signals and includes a positive signal pin and a negative signal pin. The positive signal pins of four pairs of signal pins LAN0-LAN3 are correspondingly electrically connected to the four relays A1 of the first relay unit 130 through a first group of cables 138. The negative signal pins of the four pairs of signal pins LAN0-LAN3 are correspondingly electrically connected to the four relays B1 of the second relay unit 132 through a second group of cables 139. The first and second relay units 130, 132 select and transmit the tested signals of the tested interface 20. In the embodiment, each of the cables 138, 139 is grounded through a corresponding resistor, for avoiding signal reflections.

Each pair of signal pins LAN0, LAN1, LAN2, LAN3 includes three main speeds Gen1-Gen3. In at least one embodiment, speeds of the main speeds Gen1-Gen3 are 2.5 GHz, 5 GHz, 8 GHz, respectively. The main speed Gen2 includes two secondary speeds, and the main speed Gen3 includes eleven secondary speeds. Codes of the first to fourth pairs of signal pins LAN0, LAN1, LAN2, LAN3 can be 0, 1, 2, 3, respectively.

In the embodiment, the speed display unit 151 includes a main frequency display 510 and a secondary frequency display 512. If the main speed Gen3 is displayed on the speed display unit 151, the main frequency display 510 displays “3” to mean the code of main speed Gen 3 is 3. The secondary frequency display 512 displays a code of each secondary speed of the main speed Gen 3.

During test, if the channel selection key 140 is pressed for once, the first pair of signal pins LAN0 is selected by the processor 12 to test. A first one of the relays A1 and a first one of the relays B1 electronic connected to the positive and negative of the first pair of signal pins LAN0 are controlled to turn off by the processor 12, to make the signal transmitted by the first pair of signal pins LAN0 to the oscillograph 30, through the first one of the relays A1 and the first one of the relays B1. The channel display unit 150 is controlled by the processor 12 to display “0” for showing the code of the first pair of signal pins LAN0. If the channel selection key 140 is pressed twice, the second pair of signal pins LAN1 is selected by the processor 12 to test. A second one of the relays A1 and a second one of the relays B1 electronic connected to the positive and negative of the second pair of signal pins LAN1 are controlled to turn off by the processor 12, to make the signal transmitted by the second pair of signal pins LAN1 to the oscillograph 30, through the second one of the relays A1 and the second one of the relays B1. The channel display unit 150 is controlled by the processor 12 to display “1” for showing the code of the second pair of signal pins LAN1. A speed of a pair of signal pins currently tested is controlled by the processor 12, according to a signal sent from the speed selection key 141.

Similarly, if the channel selection key 140 is pressed thrice or four times, the processor 12 selects the third pair of signal pins LAN2 or the fourth pair of signal pins LAN3 correspondingly. A third one of the relays A1 and a third one of the relays B1 electronically connected to the third pair of signal pins LAN2 are turned on. A fourth one of the relays A1 and a fourth one of the relays B1 electronic connected to the fourth pair of signal pins LAN3 are also turned on. The channel display unit 150 displays “2” or “3” for showing the code of the third pair of signal pins LAN2 or the fourth pair of signal pins LAN3. Therefore, the tested signals of the tested interface 20 can be selected through pressing the channel selection key 140.

When the first pair of signal pins LAN0 is tested, if the speed selection key 141 is pressed by a user for once, the main speed Gen 1 of the first pair of signal pins LAN0 is selected through a controlling of the processor 12. The processor 12 orders the main frequency display 510 to show the speed code “1” of the main speed Gen 1. If the speed selection key 141 is pressed by the user for twice, the main speed Gen 2 of the first pair of signal pins LAN0 is selected through the controlling of the processor 12. The processor 12 orders the main frequency display 510 to show the speed code “2” of the main speed Gen 2, and orders the secondary frequency display 512 to show a first secondary speed code “1” of the main speed Gen 2. If the speed selection key 141 is pressed by the user for thrice, the processor 12 orders the main frequency display 510 to show the speed code “2” of the main speed Gen 2, and orders the secondary frequency display 512 to show a second secondary speed code “2” of the main speed Gen 2. If the speed selection key 141 is pressed by the user for four times, the main speed Gen 3 of the first pair of signal pins LAN0 is selected. The processor 12 orders the main frequency display 510 to show the speed code “3” of the main speed Gen 3, and orders the secondary frequency display 512 to show a first secondary speed code “1” of the main speed Gen 3. Thereby, a next speed can be tested, through pressing the speed selection key 141 for one more time.

Therefore, when the user presses the channel selection key 140 and the speed selection key 141, a code and a speed of the tested signal output from a corresponding tested pin of the tested interface 20 can be tested conveniently and accurately, with a high-speed transmission through the signal transmission unit 13, and can be shown on the the channel display unit 150 and the speed display unit 151.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the appended claims should be construed to encompass all such modifications and similar arrangements.

What is claimed is:

1. A signal test device for testing a tested interface comprising a circuit board, the circuit board comprising:
a processor;
a signal transmission unit electrically connected to the processor, and comprising a first relay unit, a second relay unit, a first signal terminal electrically connected to the first relay unit, and a second signal terminal electrically connected to the second relay unit, the first and second relay units comprising a plurality of relays, the first and second signal terminals electrically connected to two signal detection terminals of an oscillograph;
an edge connector electrically connected to the tested interface, and comprising a plurality pairs of signal pins for connecting a plurality pairs of tested pins of the tested interface, each pair of signal pins for transmitting a pair of differential signals comprising a positive signal pin and a negative signal pin, the positive signal pin of each pair of signal pins electrically connected to a corresponding relay of the first relay unit through one of a plurality of cables, the negative signal pin of each pair of signal pins electrically connected to a corresponding relay of the second relay unit through one of a plurality of cables;
a channel selection key electrically connected to the processor to send a first selection signal to the processor; and
a channel display unit electrically connected to the processor;
wherein one group of tested pins of the tested interface are selected by the processor according to the first selection signal; and the relays electrically connected to the group of tested pins of the tested interface through the corresponding pair of the signal pins of the edge connector are configured to control the channel display unit displaying a code of the group of tested pins selected by the channel selection key.

2. The signal test device of claim 1, further comprising a speed selection key and a speed display unit, wherein the processor controls a speed type of the group of tested pins of the tested interface selected according to a second selection signal from the speed selection key, the speed display unit displays a speed code of the group of tested pins currently selected by the speed selection key.

3. The signal test device of claim 2, wherein the speed display unit also displays a secondary frequency code.

4. The signal test device of claim 1, wherein the circuit board comprises a front surface, the first relay unit is arranged on the front surface, and the second relay unit is arranged on a surface opposite to the front surface.

5. The signal test device of claim 1, further comprising a plurality of resistors, wherein each of the cables is electrically connected between a corresponding relay and a corresponding signal pin of the edge connector, and is grounded through a corresponding resistor.

6. The signal test device of claim 1, wherein the channel display unit comprises a plurality of digital tubes.

7. The signal test device of claim 2, wherein the speed display unit comprises a plurality of digital tubes.

8. The signal test device of claim 1, wherein the processor is a single-chip or a programmable logic controller.
